(19) United States
(12) Patent Application Publication
(10) Pub. No.: US 2014/0055131 A1
(43) Pub. Date: Feb. 27, 2014

(54) MAGNETIC FIELD SENSOR

(71) Applicants: TECHNISCHE UNIVERSITAET ILMENAU, Ilmenau (DE); FRAUNHOFER-GESELLSCHAFT ZUR FOERDERUNG DER ANGEWANDTEN FORSCHUNG E.V., Muenchen (DE)

(72) Inventors: Ruslan RYBALKO, Nuernberg (DE); Christian HOFFMAN, Nuernberg (DE); Jens HAUEISEN, Jena (DE)

(21) Appl. No.: 13/973,830

(22) Filed: Aug. 22, 2013

(30) Foreign Application Priority Data
Aug. 22, 2012 (DE) 102012214892.2

(51) Int. Cl. G01R 33/02

(52) U.S. Cl. CPC G01R 33/02
USPC 324/253

(57) ABSTRACT

Embodiments of the present invention provide a magnetic field sensor having a first current path, a second current path, a signal generator and an evaluator. The first current path has a first coil area, and the second current path has a second coil area, wherein the first coil area has windings in a first winding direction around a first magnetic core area, and wherein the second coil area has windings in a second winding direction around a second magnetic core area. The signal generator is implemented to provide an excitation current which divides into the first and second current paths. The evaluator is implemented to tap a voltage between the first and second coil areas and to detect an external magnetic field based on the voltage.

### CROSS-REFERENCE TO RELATED APPLICATIONS

This application claims priority from German Patent Application No. 102012214892.2, which was filed on Aug. 22, 2012, and is incorporated herein in its entirety by reference.

### BACKGROUND OF THE INVENTION

Embodiments of the present invention relate to a magnetic field sensor. Further embodiments of the present invention relate to a method for detecting an external magnetic field. Some embodiments relate to a device and a method for a high-resolution measurement of magnetic fields for weak field strengths and the smallest amplitudes. Some further embodiments relate to a new setup or a new model of the fluxgate sensor for detecting very weak magnetic fields.

A fluxgate magnetometer is a sensor element or measurement device for a vectorial determination of the magnetic field. Fluxgate magnetometers are also referred to as saturation core magnetometers or in the German-speaking area as “Förster-Sonde” (Förster probe) after the inventor (1937) Friedrich Förster. The English designation and the most frequently used designation in the scientific field is fluxgate sensor.

The annually disclosed articles and patents confirm the wide application spectrum of fluxgate sensors. Nowadays, fluxgate sensors may be applied in a plurality of application scenarios. They are indispensable in the precise measurement of magnetic fields, like, for example, on board of satellites and in airplanes as well as for mapping the fine structure of the terrestrial magnetic field, e.g. in finding oilfields. In airports they are used for detecting firearms, and libraries and shopping centers protect their goods from theft by using magnetic labels which are detected by fluxgate sensors. The navy uses magnetometers to track submarines underwater, and in surveying activities geographers localize boundary markers buried in the ground or covered by vegetation using fluxgate sensors.

A fluxgate sensor is a device which is sensitive to external magnetic fields. Using current technologies, both static magnetic fields with a constant field strength or quasi-static magnetic fields with a low amplitude change and also dynamic alternating fields with a variable amplitude and a frequency up to some kHz may be measured.

Using fluxgate sensors, magnetic fields with a field strength of 1 mT down to the smallest field strengths of approx. 10 pT may be measured, wherein using sensor according to standard technology, a measurement with a resolution of 10 pT is only possible with limitations (e.g. with low frequencies and with downstream averaging procedures). The terrestrial magnetic field is, for example, in a range of 30 μT . . . 40 μT, geomagnetic signals like the magnetic cardiogram (MKG) show values around 50 pT.

A classic fluxgate sensor 10 consists of a ferromagnetic, highly permeable core 12, over which two coil windings 14 and 16 are applied (primary coil 14 and secondary coil 16). In a classic construction, the secondary coil 16 is arranged so that it includes the primary coil (see FIGS. 1a and 1b).

FIG. 1a here shows the fluxgate sensor 10 without a secondary coil 16 to enable a more expressive presentation of the ferromagnetic toroidal core 12 and the primary coil 14 with the windings around the ferromagnetic toroidal core 12, while FIG. 1b shows the fluxgate sensor 10 with the secondary coil 16.

In the following, the exact functioning of the fluxgate sensor 10 illustrated in FIG. 1b is explained in more detail with reference to FIGS. 2a to 4e.

FIG. 2a shows a schematical view of the ferromagnetic toroidal core 12 and the primary coil 14 with the windings around the ferromagnetic toroidal core 12. By impressing a current i (magnetization current) into the primary coil 14, in the interior of the primary coil a magnetic field 17 with the field strength Hᵢₙ is generated, whereby the ferromagnetic toroidal core 12 is magnetized and the magnetic flow density B in the interior of the ferromagnetic toroidal core 12 is increased. The magnetic field strength Hᵢₙ and the magnetic flow density B here comprise different signs at two opposing points 20 and 22 of the ferromagnetic toroidal core 12. In case of the magnetic flow density, this is designated by B′ and B″ in the following.

In a diagram, FIG. 2b shows the hysteresis curve 24 of the ferromagnetic toroidal core 12 illustrated in FIG. 2a. As may be seen in FIG. 2b, the magnetic flow density B is determined in the ferromagnetic toroidal core 12 by the magnetic field strength Hᵢₙ. It may further be seen that, when the magnetic field strength Hᵢₙ is sufficiently increased, the magnetic flow density B, due to the saturation of the ferromagnetic toroidal core 12, increases only very slightly from the magnetic saturation field strength.

In a diagram, FIG. 2c shows the course of the current strength of the current i impressed into the primary coil 14. Here, the ordinate describes the current strength, while the abscissa describes the time t.

In a diagram, FIG. 2d shows courses of the magnetic flow density at two opposing points 20 and 22 of the ferromagnetic toroidal core 12 depending on the current i which is impressed into the primary coil 14. Here, the ordinate describes the magnetic flow density B, while the abscissa describes the time t. As may be seen in FIG. 2d, a first curve 18′ describes the course of the magnetic flow density B′ at a first point 20 of the two opposing points 20 and 22, while a second curve 18″ describes the course of the magnetic flow density B″ at a second point 22 of the two opposing points 20 and 22.

At the time t₀ the current strength of the current i is zero, so that also the magnetic flow density B at the first and second points 20 and 22 is zero. Between the times t₀ and t₁, the current strength of the current i increases, so that the magnetic flow density B′ increases at the first point 20, while the magnetic flow density B″ decreases at the second point 22, so that the magnetic flow densities B′ and B″ form opposing vectors at points 20 and 22. From time t₁, the current strength of the current i has increased so far that the ferromagnetic core 12 is in saturation and the magnetic flow density B′ reaches its maximum Bₘₐₓ at the first point 20, while the magnetic flow density B″ reaches its minimum Bₘᵢₙ at the second point 22. Between the times t₁ and t₂, the current strength shows its maximum, the magnetic flow density B′ at the first point 20 and the magnetic flow density B″ at the second point 22, however, remain (virtually) constant. At time t₂, the current strength of the current i has decreased or fallen so far that the ferromagnetic toroidal core 12 gets out of saturation. Between times t₂ and t₃, the current strength of the current i first of all decreases to zero and then reverses so that the magnetic flow density B′ decreases at the first point 20, while the magnetic flow density B″ increases at the second point 22. From time t₃, the current strength of the current i has fallen so far that the ferromagnetic core 12 is in saturation and the magnetic flow density B′ reaches its minimum Bₘᵢₙ at the first point 20, while the magnetic flow density B″ reaches its maximum Bₘₐₓ at the second point 22. Between the times t₃ and t₄, the current strength shows its minimum, the amount of the magnetic flow density B′ at the first point 20 and the amount of the magnetic flow density B″ at the second point 22 remain (virtually) constant, however. At time t₄, the current strength of the current i has again increased so far that the ferromagnetic toroidal core 12 gets out of saturation. From time t₄, the current strength of the current i increases further, so that the magnetic flow density B′ increases at the first point 20, while the magnetic flow density B″ decreases at the second point 22.

FIG. 3a shows a schematic view of the ferromagnetic toroidal core 12 and the primary coil 14 with the windings around the ferromagnetic toroidal core 12 in the presence of an external magnetic field 24. The external magnetic field 24 and the magnetic field 17 in the interior of the primary coil 14 overlay, so that the magnetic field strength Hᵢₙ, of the interior magnetic field 17 and the magnetic field strength Hₑₓₜ of the external magnetic field 24 constructively or destructively overlay, depending on the current i which is impressed into the primary coil 14.

FIG. 3b shows a diagram of the hysteresis curve 24 of the ferromagnetic toroidal core 12 illustrated in FIG. 2a.

In a diagram, FIG. 3c shows the course of the current i which is impressed into the primary coil 14.

As FIGS. 3b and 3c correspond to FIGS. 2b and 2c, reference is made to the description of FIGS. 2b and 2c.

In a diagram, FIG. 3d shows the courses of the magnetic flow density at two opposing points 20 and 22 of the ferromagnetic toroidal core 12 depending on the external magnetic field and the current i impressed into the primary coil 14. Here, the ordinate describes the magnetic flow density B, while the abscissa describes the time t. As may be seen in FIG. 2d, a first curve 18′ describes the course of the magnetic flow density B′ at a first point 20 of the two opposing points 20 and 22, while a second curve 18″ describes the course of the magnetic flow density B″ at a second point 22 of the two opposing points 20 and 22.

In contrast to FIG. 2d, it may be seen in FIG. 3d that with a positive current i the first point 20 of the ferromagnetic core 12, by the constructive overlaying of the magnetic field strength Hᵢₙ of the interior magnetic field 17 and the magnetic field strength Hₑₓₜ of the external magnetic field 24, reaches saturation already at time t₁, while the second point 22 of the ferromagnetic core 12, by the destructive overlaying of the magnetic field strength Hᵢₙ of the interior magnetic field 17 and the magnetic field strength Hₑₓₜ of the external magnetic field 24, only reaches saturation from time t₂. Accordingly, the second point 22 of the ferromagnetic core 12 already leaves saturation at time t₃, while the first point 20 of the ferromagnetic core 12 only leaves saturation from time t₄.

Analogously to what was mentioned above, with a negative current i, the second point 22 of the ferromagnetic core 12, by the constructive overlaying of the magnetic field strength Hᵢₙ of the interior magnetic field 17 and the magnetic field strength Hₑₓₜ of the external magnetic field 24, already reaches saturation at time t₅, while the first point 20 of the ferromagnetic core 12, by the destructive overlaying of the magnetic field strength Hᵢₙ of the interior magnetic field 17 and the magnetic field strength Hₑₓₜ of the external magnetic field 24, only reaches saturation from time t₆, Accordingly, the first point 20 of the ferromagnetic core 12 already leaves saturation at time t₇, while the second point 20 of the ferromagnetic core 12 only leaves saturation from time t₈.

FIG. 4a shows a schematical view of a fluxgate sensor 10. As already mentioned, the fluxgate sensor 10 comprises a ferromagnetic toroidal core 12, a primary coil 14 with windings around the ferromagnetic toroidal core 12 and a secondary coil which enwraps the ferromagnetic toroidal core 12 and the primary coil 14.

In a diagram, FIG. 4b shows the hysteresis curve 24 of the ferromagnetic toroidal core 12 illustrated in FIG. 4a.

In a diagram, FIG. 4c shows the course of the current i which is impressed into the primary coil 14.

In a diagram, FIG. 4d shows courses of the magnetic flow density at two opposing points 20 and 22 of the ferromagnetic toroidal core 12 depending on the current i which is impressed into the primary coil 14.

As FIGS. 4b to 4d correspond to FIGS. 3b to 3d, reference is made to the description of FIGS. 3b to 3d.

In a diagram, FIG. 4e shows a course of the voltage e induced into the secondary coil 16. As may be seen in FIG. 4e, a voltage is induced into the secondary coil 16 between times t₁ and t₂, t₃ and t₄, t₅ and t₆, and t₇ and t₈. The voltage e induced into the secondary coil 16 here increases (or decreases) when a first one of the two opposing points 20 and 22 (e.g. the first point 20 at time t₁) reaches saturation and reaches is maximum (or minimum) shortly before a second one of the two opposing points 20 and 22 (e.g. the second point 22 at time t₂) reaches saturation. Subsequently, the voltage induced into the secondary coil 16 increases (or decreases) rapidly. The voltage e induced into the secondary coil 16 is calculated as follows:

$$e = - s {ω}_{2} \frac{d}{d t} ( {B}^{′} + {B}^{″} )$$

Here, s is the number of windings of the secondary coil 16 and ω₂ the angular frequency, using which the secondary coil is operated.

In summary, by the primary coil (magnetization coil) 14 by means of an alternating current i at a certain frequency, the toroidal core 12 is periodically magnetized into saturation. In the secondary coil (detection coil) 16 which spatially includes or encloses the primary coil 14, the external magnetic field Hₑₓₜ and the magnetic field Hᵢₙ induced by the primary coil 14 overlay. Due to the geometrical arrangement, a destructive (or constructive) overlaying of the induced magnetic field results.

For two opposing points 20 and 22 in the ferrite core 12, the following applies:

B′=B(Hₑₓₜ−Hᵢₙ)

B″=B(Hₑₓₜ+Hᵢₙ)

This difference in the local magnetic field strengths within the toroidal core 12 induces a voltage in the secondary coil (detection coil) 16. The voltage induced in the secondary coil 16 is thus a measure for the external magnetic field 24.

In many cases, a substantial basis for measuring magnetic fields using fluxgate sensors 10 is the corresponding layout or construction of primary coil 14 and secondary coil 16: the secondary coil 16 is in most cases operated by double the frequency of the excitation current in the primary coil 14 (second harmonic, see the publication “Review of fluxgate sensors” by Pavel Ripka). Only in few cases is the secondary coil 16 operated using the same frequency, using which also the toroidal core 12 is magnetized by the alternating current i of the primary coil 14. Matching the secondary coil 16 to the first or second harmonic necessitates a corresponding calibration of the complete system (of the fluxgate sensor 10). An inaccurate calibration corrupts the measurement values and decreases the sensitivity of the fluxgate sensor 10. Additionally, by the specification of classic fluxgate sensors (number of coil windings) 10, the operating frequency of the oscillating or resonant circuit is determined.

In the publication “Review of Fluxgate Sensors” by Pavel Ripka, some widespread types of fluxgate magnetometers are described, the functioning of the sensors is discussed and different tapping methods of the signals are considered.

In the publication “A New Type of Fluxgate Magnetometer for Low Magnetic Fields” by Derac Son, a new method of detecting magnetic signals is described. This method enables measuring weak magnetic fields.

The existing basic principle of fluxgate sensors 10 necessitates a secondary winding 16 for measuring the induced voltage. For very sensitive fluxgate sensors 10, secondary coils 16 with a large number of windings are necessitated (sensitivity). This leads to the disadvantages mentioned in the following. First, it leads to large mechanical dimensions, which is why no further miniaturization of the fluxgate sensor 10 is possible. Second, it leads to high parasitic capacities between the individual coil windings, which lead to a oscillating circuit behavior. Third, it leads to an increased parasitic resistance due to the many coil windings, which is why more losses are generated.

Apart from that, for the above-described operating type (measuring the induced voltage in the secondary coil 16 as a second harmonic of the excitation current in the primary coil) a corresponding matching and calibration of the oscillating circuit is necessitated.

In summary, the following disadvantages of current fluxgate sensors 10 are the characteristics mentioned in the following. First, two coil windings are necessitated (primary and secondary coils 14 and 16). Second, a matching of the secondary oscillating circuit 16 is necessitated (matching to the first or second harmonic of the primary oscillating circuit 14). Third, by determining the number of windings in the primary and secondary coils 14 and 16, the classic fluxgate sensor 10 has a determined operating frequency. Fourth, measurements in the secondary coil 16 have to be executed at a determined frequency and thus limit the maximum measurable frequency of the external magnetic field (sampling theorem). Fifth, with a low number of secondary windings, only a low sensitivity can be acquired (only great differences of the external magnetic field). Sixth, with sensitive fluxgate sensors 10 with a high number of secondary windings, due to the mechanical preconditions a further miniaturization is hardly possible.

WO 2010/020648 A1 shows a fluxgate sensor with a ferromagnetic core, an excitation coil and a pick-up coil. Instead of using separate coils for the excitation coil and the pick-up coil, the excitation coil and the pick-up coil are implemented by means of a conventional coil. The coil is here divided into two halves which are serially interconnected and comprise a common central terminal. The fluxgate sensor uses a current source which impresses an alternating current into the coil with the two serially interconnected halves. In use, the voltage induced into the two halves of the coil are summed up and evaluated.

### SUMMARY

According to an embodiment, a magnetic field sensor may have a first current path having a first coil area and a second current path having a second coil area, wherein the first coil area has windings in a first winding direction around a first magnetic core area, and wherein the second coil area has windings in a second winding direction around a second magnetic core area, and wherein the first coil area and the second coil area pass in parallel to each other; a signal generator which is implemented to provide an excitation current which divides into the first and second current paths; and an evaluator which is implemented to tap a voltage between the first and second coil areas to detect an external magnetic field based on the voltage.

According to another embodiment, a method for detecting an external magnetic field may have the steps of providing an excitation current which divides into a first current path with a first coil area and a second current path with a second coil area, wherein the first coil area has windings in a first winding direction around a first magnetic core area, wherein the second coil area has windings in a second winding direction around a second magnetic core area, and wherein the first coil area and the second coil area pass in parallel to each other; tapping a voltage between the first and second coil areas; and detecting the external magnetic field based on the voltage between the first and second coil areas.

According to another embodiment, a computer program may execute a method for detecting an external magnetic field which may have the steps of providing an excitation current which divides into a first current path with a first coil area and a second current path with a second coil area, wherein the first coil area has windings in a first winding direction around a first magnetic core area, wherein the second coil area has windings in a second winding direction around a second magnetic core area, and wherein the first coil area and the second coil area pass in parallel to each other; tapping a voltage between the first and second coil areas; and detecting the external magnetic field based on the voltage between the first and second coil areas, when the computer program is executed on a computer or microprocessor.

Embodiments of the present invention provide a magnetic field sensor with a first current path, a second current path, a signal generator and an evaluation means. The first current path comprises a first coil area and the second current path comprises a second coil area, wherein the first coil area comprises windings in a first winding direction around a first magnetic core area, and wherein the second coil area comprises windings in a second winding direction around a second magnetic core area. The signal generator is implemented to provide an excitation current which is divided onto the first and second current paths. The evaluation means is implemented to tap a voltage between the first and second coil areas in order to detect an external magnetic field based on the voltage.

Further embodiments of the present invention provide a magnetic field sensor with a first and second coil area, a signal generator and an evaluation means. The first coil area comprises windings in a first winding direction around a first magnetic core area, wherein the second coil area comprises windings in a second winding direction around a second magnetic core area. The signal generator is implemented to impress a first current into the first coil area and a second current into the second coil area. The evaluation means is implemented to tap a voltage between the first and second coil areas in order to detect an external magnetic field based on the voltage.

In embodiments, the first coil area comprises windings in a first winding direction around a first magnetic core area, wherein the second coil area comprises windings in a second winding direction around a second magnetic core area. By providing an excitation current which divides into the first and second current paths, in the first coil area a first magnetic field H₁ results which magnetizes the first magnetic core area and causes a first magnetic flow density B′ directed into a first direction, while in the second coil area a second magnetic field H₂ results which magnetizes the second magnetic core area and causes a second magnetic flow density B″ directed into a second direction. By an external magnetic field directed into the first direction, the first magnetic flow density B′ in the first core area is increased, while the second magnetic flow density B″ in the second core area is reduced. This leads to the fact that, when the excitation current is simultaneously increased, the first magnetic core area reaches saturation at a first time, while the second magnetic core area reaches saturation at a second time. Between the first time and the second time, the first and second coil areas comprise different electric characteristics, so that the evaluation means, based on the voltage between the first coil area and the second coil area, may detect the external magnetic field.

Further embodiments provide a method for detecting an external magnetic field. In a first step, an excitation current is provided which divides into a first current path with a first coil area and a second current path with a second coil area, wherein the first coil area comprises windings in a first winding direction around a first magnetic core area, while the second coil area comprises windings in a second winding direction around a second magnetic core area, and wherein the first coil area and the second coil area pass in parallel to each other. In a second step, a voltage between the first and second coil areas is tapped. In a third step, the external magnetic field is detected based on the voltage difference between the first and second coil areas.

Further embodiments provide a method for detecting an external magnetic field. In a first step, a first current is impressed into a first coil area, and a second current is impressed into a second coil area, wherein the first coil area comprises windings in a first winding direction around a first magnetic core area, and wherein the second coil area comprises windings in a second winding direction around a second magnetic core area. In a second step, a voltage between the first and second coil areas is tapped. In a third step, the external magnetic field is detected based on the voltage difference between the first and second coil areas.

### BRIEF DESCRIPTION OF THE DRAWINGS

Embodiments of the present invention will be detailed subsequently referring to the appended drawings, in which:

FIG. 1a is a schematical view of a fluxgate sensor without a secondary coil;

FIG. 1b is a schematical view of the fluxgate sensor with a secondary coil;

FIG. 2a is a schematical view of the ferromagnetic toroidal core and the primary coil with the windings around the ferromagnetic toroidal core.

FIG. 2b is, in a diagram, the hysteresis curve of the ferromagnetic toroidal core illustrated in FIG. 2a;

FIG. 2c is, in a diagram, the course of the current strength of the current impressed into the primary coil;

FIG. 2d is, in a diagram, the courses of the magnetic flow density at two opposing points of the ferromagnetic toroidal core depending on the current impressed into the primary coil;

FIG. 3a is a schematic view of the ferromagnetic toroidal core and the primary coil with the windings around the ferromagnetic toroidal core in the presence of an external magnetic field;

FIG. 3b is, in a diagram, the hysteresis curve of the ferromagnetic toroidal core illustrated in FIG. 3a;

FIG. 3c is, in a diagram, the course of the current strength of the current impressed into the primary coil;

FIG. 3d is, in a diagram, courses of the magnetic flow density at two opposing points of the ferromagnetic toroidal core depending on the external magnetic field and the current impressed into the primary coil;

FIG. 4a is a schematical view of a fluxgate sensor;

FIG. 4b is, in a diagram, the hysteresis curve of the ferromagnetic toroidal core illustrated in FIG. 4a;

FIG. 4c is, in a diagram, the course of the current strength of the current impressed into the primary coil;

FIG. 4d is, in a diagram, courses of the magnetic flow density at two opposing points of the ferromagnetic toroidal core depending on the external magnetic field and the current impressed into the primary coil;

FIG. 4e is, in a diagram, a course of the voltage induced into the secondary coil;

FIG. 5 is a block diagram of a magnetic field sensor according to one embodiment of the present invention;

FIG. 6a is a block diagram of a magnetic field sensor according to a further embodiment of the present invention;

FIG. 6b is, in a diagram, the course of the current strength of the first current impressed into the first coil and the second current impressed into the second coil;

FIG. 6c is, in a diagram, the course of the first magnetic flow density in the first core area and the course of the second magnetic flow density in the second core area;

FIG. 6d is, in a diagram, the course of the output voltage of the differential amplifier;

FIG. 7 is a block diagram of a magnetic field sensor according to one embodiment of the present invention;

FIG. 8a is, in a diagram, the hysteresis curve of the ferromagnetic toroidal core illustrated in FIG. 7, wherein a first point designates the first magnetic flow density and a second point designates the second magnetic flow density;

FIG. 8b is, in a diagram, the hysteresis curve of the ferromagnetic toroidal core illustrated in FIG. 7, wherein a first point designates the first magnetic flow density and a second point designates the second magnetic flow density;

FIG. 8c is, in a diagram, the hysteresis curve of the ferromagnetic toroidal core illustrated in FIG. 7, wherein a first point designates the first magnetic flow density and a second point designates the second magnetic flow density; and

FIG. 9 is, in a diagram, the course of the triangular voltage, the output voltage of the differential amplifier and the output voltage of the peak value detector.

### DETAILED DESCRIPTION OF THE INVENTION

In the following description, in the figures like or seemingly like elements are designated by the same reference numerals, so that the description is mutually interchangeable in the different embodiments.

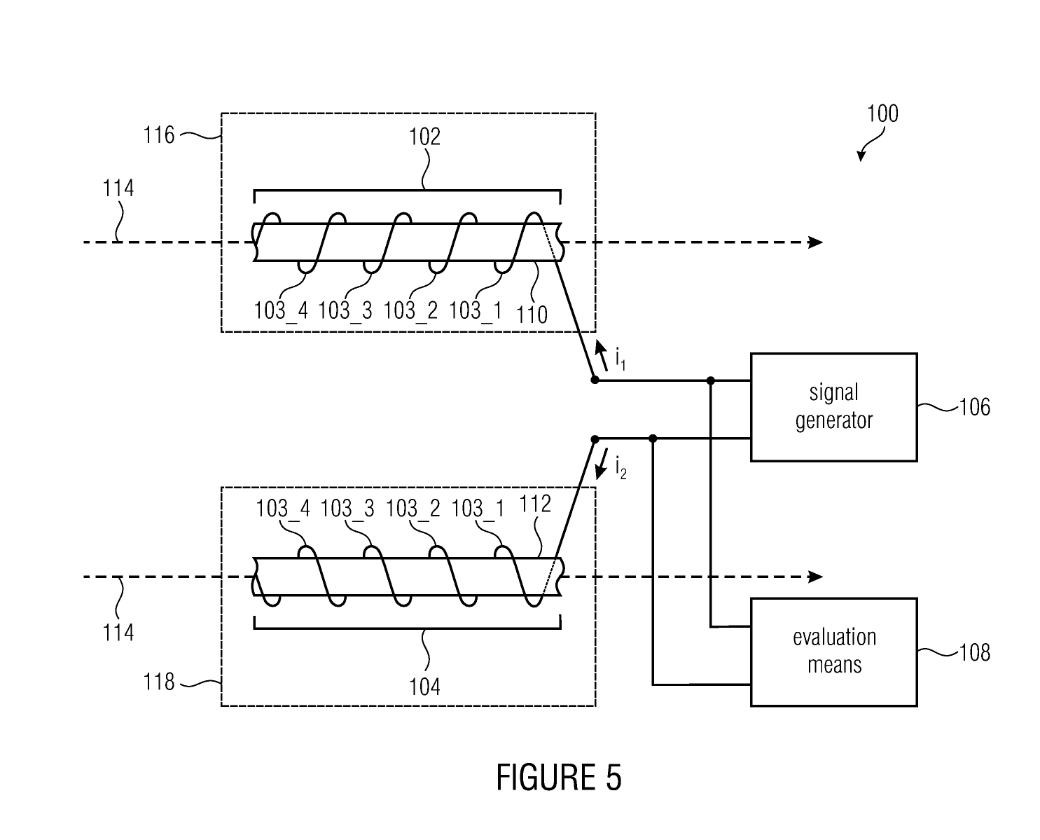

FIG. 5 shows a block diagram of a magnetic field sensor 100 according to an embodiment of the present invention. The magnetic field sensor 100 comprises a first current path 116, a second current path 118, a signal generator 106 and an evaluation means 108. The first current path 116 comprises a first coil area 102 and the second current path 118 a second coil area 104, wherein the first coil area 102 comprises windings in a first winding direction around a first magnetic core area 110, and wherein the second coil area 104 comprises windings in a second winding direction around a second magnetic core area 110. The signal generator 106 is implemented to provide an excitation current i which divides into the first and second current paths 116 and 118. The evaluation means 108 is implemented to tap a voltage between the first and second coil areas 102 and 104 and to detect an external magnetic field 114 based on the voltage.

In other words, in embodiments, the magnetic field sensor 100 comprises a first and a second coil area 102 and 104, a signal generator 106 and an evaluation means 108. The first coil area 102 comprises windings 103_1 to 103_{—}n in a first winding direction around a first magnetic core area 110, wherein the second coil area 104 comprises windings 105_1 to 105_{—}m in a second winding direction around a second magnetic core area 112. The signal generator 106 is implemented to impress a first current i₁ into the first coil area 102 and a second current i₂ into the second coil area 104. The evaluation means 108 is implemented to tap a voltage between the first and second coil areas 102 and 104 to detect an external magnetic field 114 based on the voltage.

In embodiments, the first coil area 102 comprises windings 103_1 to 103_{—}n in a first winding direction around a first magnetic core area 110, while the second coil area 104 comprises windings 105_1 to 105_{—}m in a second winding direction around a second magnetic core area 112. By providing an excitation current which divides into the first current path and the second current path, in the first coil area 102 a first magnetic field with a first magnetic field strength H₁ (in the interior of the first coil area 102) is generated, whereby the first magnetic core area 110 is magnetized and a first magnetic flow density B′ is increased regarding its amount in the first magnetic core area 110, while in the second coil area 102 a second magnetic field with a second magnetic field strength H₂ (in the interior of the second coil area 102) is generated, whereby also the second magnetic core area 112 is magnetized and a second magnetic flow density B″ is increased regarding its amount in the second magnetic core area 110. Due to the fact that the first coil area 102 comprises windings in a first winding direction, while the second coil area 104 comprises windings in a second winding direction, the first magnetic field strength H₁ is directed into a first direction, while the second magnetic field strength H₂ is directed into a second direction. In the presence of an external magnetic field with an external magnetic field strength Hₑₓₜ, the first magnetic field strength H₁ and the external magnetic field strength Hₑₓₜ overlay depending on the direction of the external magnetic field strength Hₑₓₜ and the first current e.g. constructively (or destructively), whereby the first magnetic flow density B′ is increased (or reduced), while the second magnetic flow density and the magnetic flow density of the external magnetic field destructively (or constructively) overlay depending on the direction of the external magnetic field strength Hₑₓₜ and the second current i₂, whereby the second magnetic flow density B″ is reduced (or increased). This leads to the fact that with a corresponding excitation current which divides into the first current path and the second current path the first magnetic core area reaches saturation at a first time, while the second magnetic core area 112 reaches saturation at a second time. Between the first time at which the first magnetic core area 110 reaches saturation and the second time at which the second magnetic core area 112 reaches saturation, the first coil area 102 and the second coil area 104 show different electric characteristics, so that the evaluation means 108 may detect the external magnetic field based on the voltage difference between the first coil area 102 and the second coil area 104.

In embodiments, the signal generator 106 may be implemented to provide an excitation current i which divides into the first current path 116 and the second current path 118. Thus, in the first current path 116 a first current flows, and in the second current path i₂ a second current flows. The sum of the first current i₁ and the second current i₂ can be equal to the excitation current i (i=i₁+i₂) In embodiments, the first current path 116 and the second current path 118 may be symmetrical, so that the excitation current i equally divides into the first current path 116 and the second current path 118 (i₁=i₂).

In embodiments, the first winding direction and the second winding direction can be different, e.g. opposing. For example, the windings 103_1 to 103_{—}n of the first coil area 102 may be arranged helically (or in a screw-like manner) clockwise around the first core area 110, while the windings 105_1 to 105_{—}m of the second coil area 10 may be arranged helically (or in a screw-like manner) counterclockwise around the second core area 112.

Further, the first coil area 102 and the second coil area 104 can basically pass in parallel to each other. For example, an external magnetic field 114 with an external magnetic field strength Hₑₓₜ, which passes basically in parallel to the first and second coil areas 102 and 104, may, e.g., lead to a constructive (or destructive) overlaying of the first magnetic field strength H₁ of the first coil area 102 and the magnetic field strength Hₑₓₜ of the external magnetic field 114 and to a destructive (or constructive) overlaying of the second magnetic field strength H₂ of the second coil area 104 and the magnetic field strength Hₑₓₜ of the external magnetic field 114. Of course, the magnetic field sensor 100 may also be utilized to detect an external magnetic field 114 whose magnetic flow density passes at an angle α to the first and/or second coil area 102 and 104, wherein the angle α may be smaller than 80°, 70°, 60°, 50°, 40°, 30°, 20°, 10°, 5°, 3°, or 1°.

Further, a number n of windings (winding number) 103_1 to 103_{—}n of the first coil area may be equal to a number m of windings (winding number) 105_1 to 105_{—}m of the second coil area 104 (n=m), wherein n and m may be natural numbers. For example, the first and second coil areas 102 and 104 may each comprise more than 5, 10, 20, 30, 40, 50, 60, 70, 80, 90, 100, 150, 200, 300, 400, 500, 600, 700, 800, 900 or 1000 windings. Of course, the first and second coil areas 102 and 104 may also comprise different winding numbers, wherein in this case the sensitivity of the magnetic field sensor 100 is reduced.

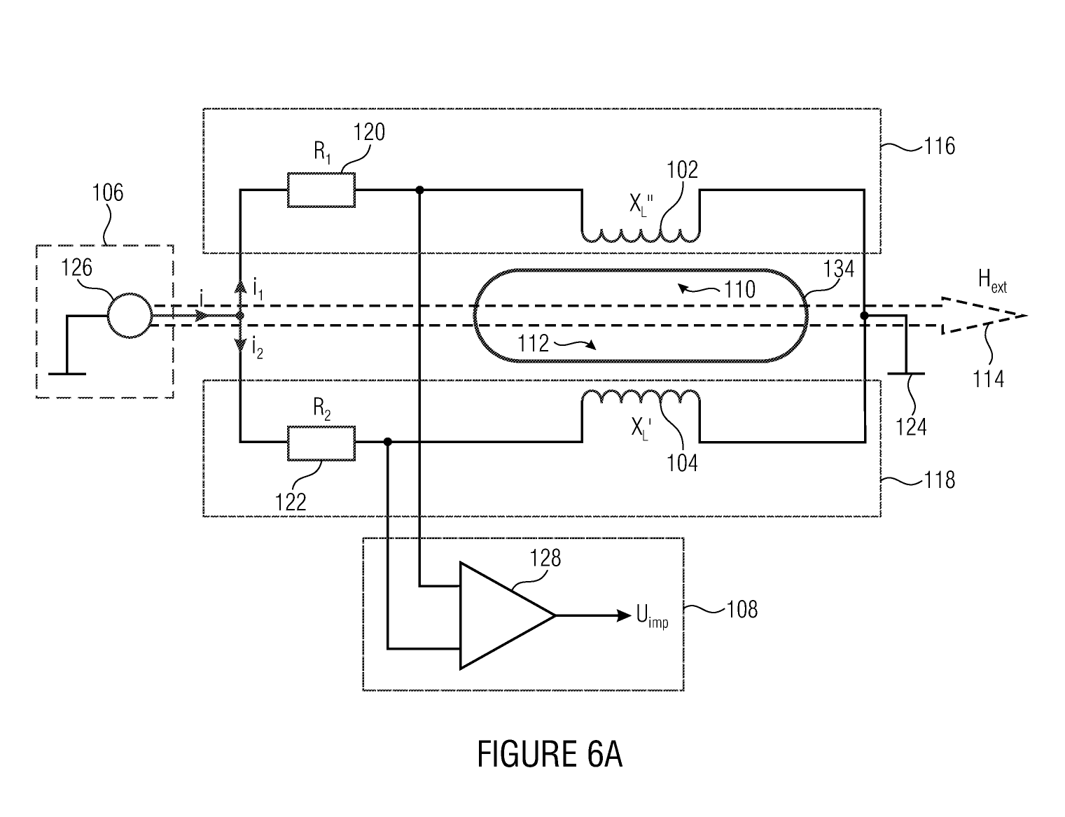

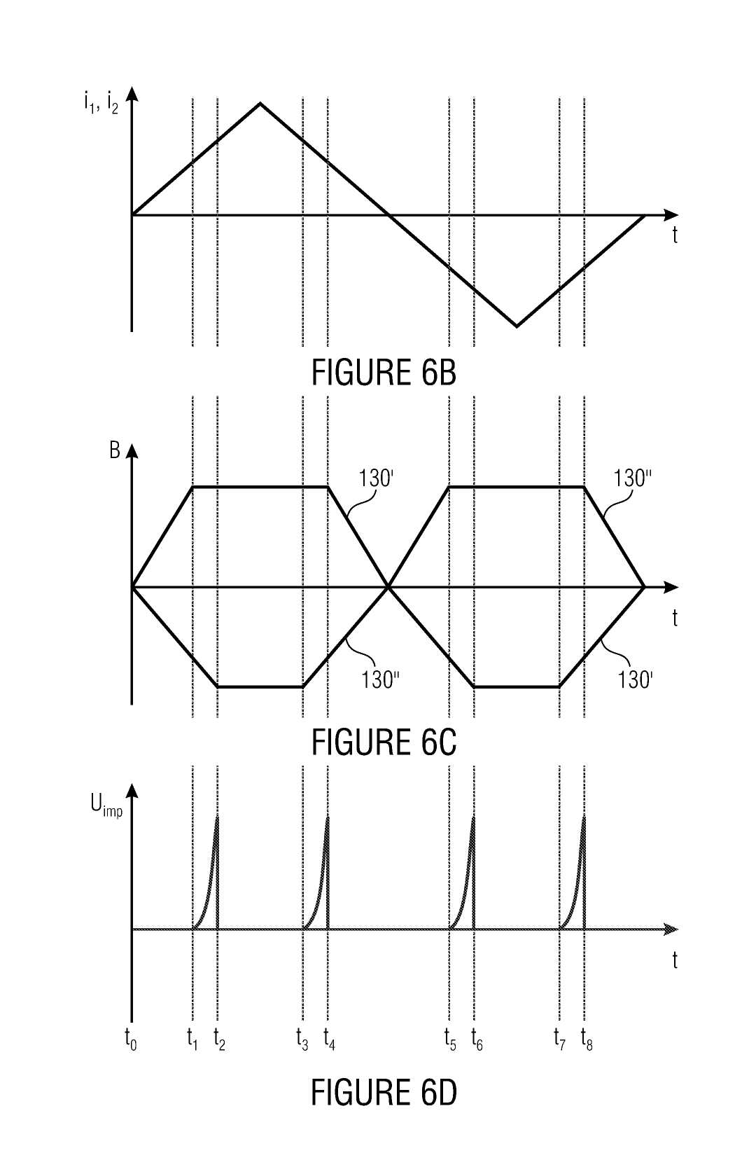

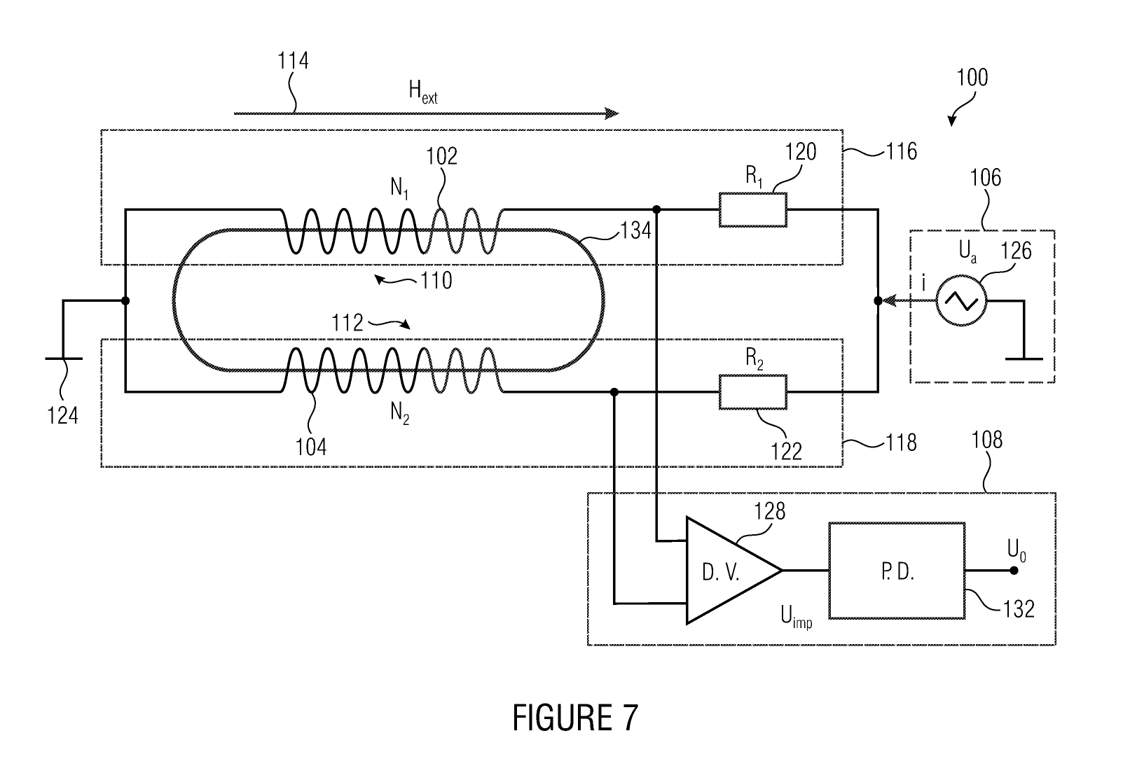

In embodiments, the magnetic field sensor 100 may comprise a magnetic core including the first and second magnetic core areas 110 and 112. In other words, the magnetic field sensor 100 may comprise a magnetic core 134 (see, e.g., FIGS. 6a and 7), wherein a first area of the magnetic core forms the first magnetic core area 110 and wherein a second area of the magnetic core forms the second magnetic core area 112. For example, the magnetic core may be a ferromagnetic or ferrimagnetic toroidal core, wherein opposing (e.g. spaced apart) areas of the toroidal core may form the first core area 110 and the second core area 112.

In embodiments, the magnetic core may e.g. be a toroidal core, a double strip core, a double rod core, a rectangular core, a square core, a hexagonal core or an octagonal core.

In embodiments, the magnetic field sensor 100 may comprise a first and second magnetic core, wherein the first magnetic core includes the first core area 110 and wherein the second magnetic core includes the second core area. In other words, the magnetic field sensor 100 may comprise a first and second magnetic core, wherein at least one area of the first magnetic core forms the first core area and wherein at least one area of the second magnetic core forms the second core area. For example, the first and second magnetic cores may be ferromagnetic or ferrimagnetic cores.

In embodiments, the magnetic field sensor 100 may comprise a first and second coil, wherein the first coil includes the first coil area 102 and wherein the second coil includes the second coil area 104. In other words, the magnetic field sensor 100 may comprise a first and second coil, wherein at least one area of the first coil forms the first coil area 102, and wherein at least one area of the second coil forms the second coil area 104. The first coil area 102 may thus be the area of the first coil comprising windings 103_1 to 103_{—}n around the first magnetic core area 110, while the second coil area 112 may be the area of the second coil comprising windings 105_1 to 105_{—}m around the second magnetic core area 112.

FIG. 6a shows a block diagram of a magnetic field sensor 100 according to a further embodiment of the present invention. The magnetic field sensor 100 comprises a first and a second coil 102 and 104, wherein the first coil 102 forms the first coil area 102, and wherein the second coil 104 forms the second coil area 104.

Further, the magnetic field sensor 100 may comprise a bridge circuit, wherein the first current path 116 forms a first bridge branch of the bridge circuit, and wherein the second current path 118 forms a second bridge branch of the bridge circuit 118. The evaluation means 108 may be implemented to tap the voltage between the first and second bridge branches 116 and 118.

Further, the magnetic field sensor 100 may comprise a first and second resistor 120 (R₁) and 122 (R₂), wherein the first bridge branch 116 includes the first resistor 120 and the second bridge branch 118 includes the second resistor 122.

The first and second bridge branches 116 and 118 may each be connected in series between a reference terminal 124 and the signal generator 106, wherein the reference terminal 124 may be implemented to provide a reference potential. For example, the reference terminal 124 may be a mass terminal 124 which is implemented to provide a mass potential. Of course, the reference terminal 124 may also provide a different potential.

The signal generator 106 may be implemented to generate a triangular voltage, wherein the first and second currents i₁ and i₂ are based on the triangular voltage. For example, the signal generator 106 may comprise a triangular voltage source 126 which is implemented to provide the triangular voltage. In this case, the first and second resistors 120 and 122 may be utilized to set the first and second currents i₁ and i₂.

The evaluation means 108 may comprise a differential amplifier 128 which is implemented to tap and amplify the voltage difference between the first and second coil areas 102 and 104 in order to acquire an output voltage Uᵢₘₚ (impulse voltage).

By impressing the first current i₁ into the first coil 102, a first magnetic field with a first magnetic field strength H₁ is generated (in the interior of the first coil area 102), whereby the first magnetic core area 110 is magnetized and the amount of the first magnetic flow density B′ in the first magnetic core area 110 increases. By impressing the second current i₂ into the second coil 102 a second magnetic field with a second magnetic field strength H₂ is generated (in the interior of the second coil area 102), whereby also the second magnetic core area 112 is magnetized and the amount of the second magnetic flow density B″ in the second magnetic core area 110 increases. The external magnetic field strength Hₑₓₜ overlays the first magnetic field strength H₁ depending on the direction of the external magnetic field strength Hₑₓₜ and the first current i₁ e.g. constructively (or destructively), whereby the first magnetic flow density B′ is increased (or reduced), while the external magnetic field strength Hₑₓₜ overlays the second magnetic field strength H₂ depending on the direction of the external magnetic field strength Hₑₓₜ and the second current i₂, e.g. destructively (or constructively), whereby the second magnetic flow density B″ is reduced (or increased). This leads to the fact that with a corresponding first current i₁ and second current i₂ the first magnetic core area 110 reaches saturation at a first time t₁, while the second magnetic core area 112 reaches saturation at a second time t₂ (see FIG. 6c). Between the first time t₁ at which the first magnetic core area 110 reaches saturation and the second time t₂ at which the second magnetic core area 112 reaches saturation, the first coil 102 and the second coil 104 comprise different electric characteristics, so that the evaluation means 108 may detect the external magnetic field 114 based on the voltage between the first coil 102 and the second coil 104.

In a diagram, FIG. 6b shows the course of the current strength of the first current i₁ which is impressed into the first coil 102 and the second current i₂ which is impressed into the second coil 102. Here, the ordinate describes the current strength, while the abscissa describes the time.

In a diagram, FIG. 6c shows the course 130′ of the first magnetic flow density B′ in the first magnetic core area 110 and the course 130″ of the second magnetic flow density B″ in the second magnetic core area 112. Here, the ordinate describes the magnetic flow density, while the abscissa describes the time.

It may be seen in FIG. 6c that with a positive first and second current i₂ and i₂ the first magnetic core area 110 reaches saturation already at time t₁ by the constructive overlaying of the external magnetic field strength Hₑₓₜ and the first magnetic field strength H₁, while the second magnetic core area 112 reaches saturation only at time t₂ by the destructive overlaying of the external magnetic field strength Hₑₓₜ and the second magnetic field strength H₂. Accordingly, the second magnetic core area 112 leaves saturation already at time t₃, while the first magnetic core area only leaves saturation at time t₄.

With a negative first and second current i₂ and i₂, the second magnetic core area 112 reaches saturation already at time t₅ by the constructive overlaying of the external magnetic field strength Hₑₓₜ and the second magnetic field strength H₂, while the first magnetic core area only reaches saturation at time t₆ by the destructive overlaying of the external magnetic field strength Hₑₓₜ and the first magnetic field strength H₁. Accordingly, the first magnetic core area 110 leaves saturation already at time t₇, while the second magnetic core area 112 only leaves saturation at time t₈.

In a diagram, FIG. 6d shows the course of the output voltage Uᵢₘₚ of the differential amplifier 128. Here, the ordinate describes the voltage, while the abscissa describes the time. As may be seen in FIG. 6d, the output voltage Uᵢₘₚ of the differential amplifier 128 comprises voltage impulses between the times t₁ and t₂, t₃ and t₄, t₅ and t₆ and t₇ and t₈. The voltage impulses here increase when a first area of the two core areas 110 and 112 reaches saturation and reach their maximum shortly before a second area of the two core areas 110 and 112 reaches saturation. Subsequently, the voltage impulses rapidly decrease.

In other words, embodiments of the present invention describe a new method to execute the measurement of magnetic field strengths 114 easily and precisely (with a high time resolution and thus a high frequency measurement area).

The laid out sensor concept eliminates the secondary coil from the circuit topology and thus frees the complete system from existing dependencies with respect to tuning the oscillating circuit, fixed operating frequency or limitation of the measurable frequencies and possibilities with respect to miniaturization in particular with highly sensitive sensors.

A substantial particularity of the present invention is that, beyond the classical measurement value spectrum of existing fluxgate sensors, field strengths of very weak magnetic fields may be measured precisely. Apart from that, alternating fields with very high frequencies may be registered.

In the following, substantial improvements of embodiments of the present invention with respect to existing technologies are listed. First, embodiments enable a realization of the fluxgate sensor 100 with only one coil winding (divided primary coil). Second, embodiments make it possible to freely select the frequency for the excitation current in the primary coil (magnetization). Third, in embodiments, no tuning of the oscillating circuit is necessitated (as the secondary coil is omitted). Fourth, embodiments enable an extension of the measurable frequency spectrum (from a low-frequency range up to a high-frequency range, e.g. from DC to 1 MHz or even infinity instead of currently some 10 kHz). The extension of the measurement of external magnetic alternating fields may thus be executed from the current limit of some 10 kHz (classic technology) theoretically without limitation (due to the sensor principle). The only limitations are the signal generator and the evaluation unit. Fifth, embodiments comprise an improved sensitivity without a higher winding number. Sixth, embodiments comprise smaller dimensions with a high sensitivity. Seventh, in embodiments, due to the sensor concept, a further miniaturization is easily possible. Eighth, embodiments provide more flexibility with respect to the geometric design of the fluxgate sensor 100. Ninth, embodiments comprise an improved temporal resolution capacity. Tenth, embodiments enable a precise measurement also of very weak magnetic fields.

In contrast to known fluxgate sensors, the inventive magnetic sensor comprises no capacitive coupling in the current paths. Apart from that, in contrast to known fluxgate sensors, the voltage difference is only measured across the coils 102 and 104. Further, in contrast to known fluxgate sensors, the current paths 102 and 104 are excited in parallel.

The basic approach of the present invention is to detect the measurement of magnetic fields 114 via a current strength change in a divided (primary) coil 102 and 104 which is wound onto a toroidal core 134. The measurement is thus not executed via the detection of an induced voltage in a secondary coil as with classic fluxgate sensors. The current strength change results due to the overlaying of external magnetic fields 114 and an induced magnetization in the toroidal core 134.

Fluxgate sensors consisting of a toroidal core of soft magnetic materials have long been known in the field of magnetic research [P. Ripka. Magnetic Sensors and Magnetometers. Artech House Publishers, 81-83, 2001.] This type of fluxgate sensor is already very sensitive. In experimental research, using this type of fluxgate sensor, measurements may be executed with low magnetic noise. This characteristic is also used and implemented in the present invention.

The toroidal core 134 was manufactured in an oval shape and consists of some windings of a thin, soft magnetic band with a very high magnetic permeability. The band is made of a cobalt-iron alloy characterized by high magnetic permeability μ and by a low coercive field strength. Such alloys comprise a low magnetic noise level and only comprise a low measure of anisotropy. Further, these alloys comprise good temperature stability and high resistivity. This makes the core 134 specially suitable for use at high frequencies.

For the detection and measurement of induced voltages resulting due to magnetic field overlaying in the interior of the toroidal core 134 of a fluxgate sensor, in a classic construction a secondary coil is used as the main element. This concept, however, presents a complicated realization of fluxgate sensors. The present invention describes a new method, wherein the use of a secondary coil may be omitted and only a divided primary coil 102 and 104 is used, which is applied to a toroidal core 134. The measurement of the magnetic field overlaying in the interior of the toroidal core 134 is then measured here via a current strength change in the divided primary coil 102 and 104.

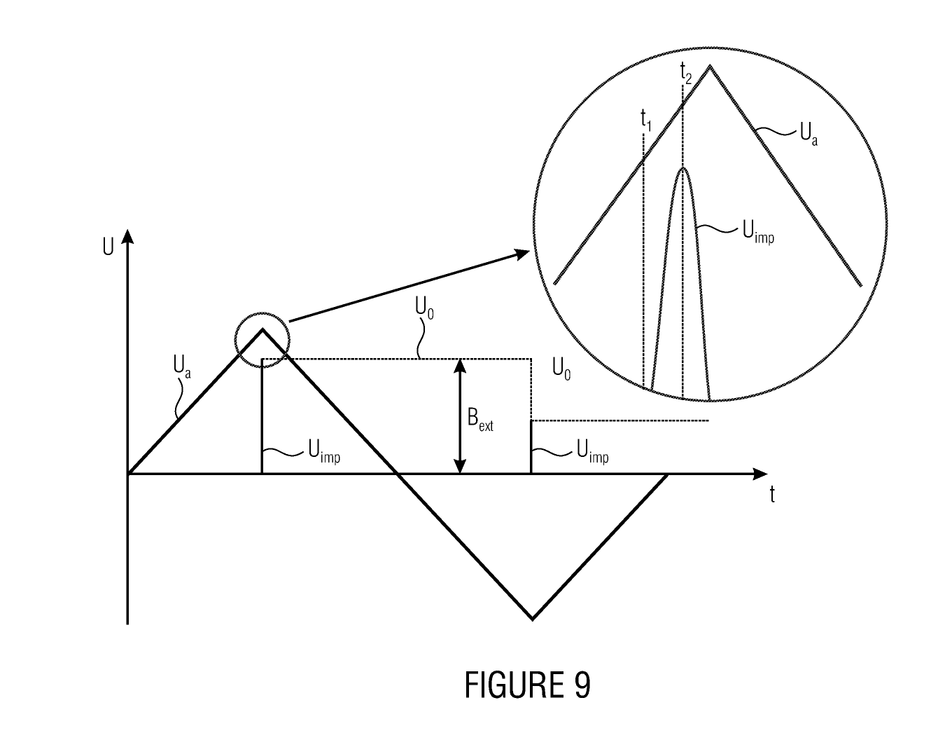

FIG. 7 shows a block diagram of a magnetic field sensor 100 according to one embodiment of the present invention. The magnetic field sensor 100 comprises a first coil 102 with windings in a first winding direction around a first magnetic core area 110 of a magnetic toroidal core 134, a second coil 104 with windings in a second winding direction around a second magnetic core area 112 of the magnetic toroidal core 134, a first resistor 120 and a second resistor 122, a signal generator 106 and an evaluation means 108. The first coil 102 and the first resistor 120 are connected in series and form a first bridge branch 116 of a bridge circuit. The second coil 104 and the second resistor 122 are connected in series and form a second bridge branch 118 of the bridge circuit. The first and second bridge branches 116 and 118 are here each connected in series between a reference terminal 124 and the signal generator 126. The signal generator 106 comprises a triangular voltage source 126 which is implemented to apply a triangular voltage Uₐ to the first and second bridge branches 116 and 118. The evaluation means 108 comprises a differential amplifier 128 which is implemented to tap a voltage between the first and second bridge branches 116 and 118 and amplify the same to acquire an output voltage Uᵢₘₚ. Further, the evaluation means 108 comprises a peak value detector 132 which is implemented to detect a peak value of the output voltage Uᵢₘₚ of the differential amplifier 128 and to output the detected peak value as an output voltage U₀ of the evaluation means 108. In other words, the evaluation means 108 comprises a peak value detector 132 which is implemented to detect a peak value of the output voltage Uᵢₘₚ of the differential amplifier 128 and maintain the same (e.g. for a given time period or up to the detection of a peak value temporally following the peak value) (dashed line 150 in FIG. 9). The peak value of the output voltage Uᵢₘₚ is here a measure for the external magnetic field 114 or the external magnetic flow density Bₑₓₜ (see FIG. 9).

In other words, the sensor 100 includes an amorphous or ferromagnetic toroidal core 134 and a divided primary coil (excitation coil N₁ (102) and N₂ (104)). The coils 102 and 104 are located on two sides of the toroidal core 134. Via the resistors 120 and 122, the generator 106 of a triangular signal, which generates the alternating voltage Uₐ for the exciting magnetic auxiliary field and thus impresses the magnetization current Iₐ (i₁ and i₂) into the primary coil, is connected to the coils N₁ and N₂.

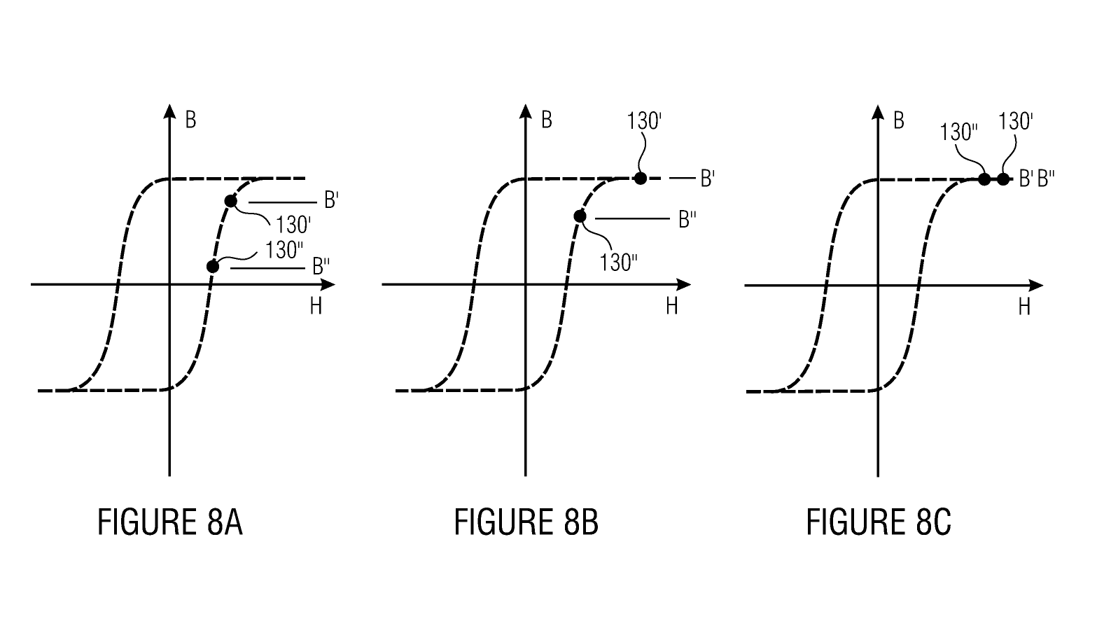

The resistors R₁ and R₂ serve as current dividers and for the limitation of the coil current. In the two current paths across R1 and N1 and across R2 and N2 each a voltage divider results for Uₐ. This voltage divider is equal when no external magnetic field 114 prevails. If an external magnetic field is active, an induced voltage results in the coil windings of the divided primary coil 102 and 104. Due to the geometrical, opposing arrangements N1 and N2 a constructive or destructive overlay with the external magnetic field 114 results in the two coils 102 and 104. This leads to the fact that the magnetization of the toroidal core 134 at N1 and N2 may take on different intensities on the hysteresis loop (see FIGS. 8a to 8c) and thus comprise a different reserve for magnetic saturation.

B′=Bₑₓₜ+Bᵢₙ

B″=Bₑₓₜ−Bᵢₙ

In a diagram, FIG. 8a shows the hysteresis curve 140 of the ferromagnetic toroidal core 134 illustrated in FIG. 7, wherein a first point 130′ designates the first magnetic flow density B′ and a second point 130″ designates the second magnetic flow density B. Here, the ordinate describes the magnetic flow density, while the abscissa describes the magnetic field strength. It may be seen in the example illustrated in FIG. 8a, that the first magnetic flow density B′ in the first magnetic core area 110 is greater than the second magnetic flow density B″ in the second magnetic core area 112. A constructive overlaying of the external magnetic field Hₑₓₜ and the first magnetic field H₁ of the first coil 102 thus leads to an increase of the first magnetic flow density B′, while a destructive overlaying of the external magnetic field Hₑₓₜ and the second magnetic field H₂ of the second coil 104 leads to a reduction of the second magnetic flow density B.

In a diagram, FIG. 8b shows the hysteresis curve 140 of the ferromagnetic toroidal coil 134 illustrated in FIG. 7, wherein a first point 130′ designates the first magnetic flow density B′ and a second point 130″ designates the second magnetic flow density B. Here, the ordinate describes the magnetic flow density, while the abscissa describes the magnetic field strength. It may be seen in the example illustrated in FIG. 8b that an increase of the first and second currents i₁ and i₂ leads to an increase of the first magnetic flow density B′ and the second magnetic flow density B″, wherein the first magnetic core area 110 is already in saturation.

In a diagram, FIG. 8c shows the hysteresis curve 140 of the ferromagnetic toroidal core 134 illustrated in FIG. 7, wherein a first point 130′ designates the first magnetic flow density B′ and a second point 130″ designates the second magnetic flow density B. Here, the ordinate describes the magnetic flow density, while the abscissa describes the magnetic field strength. It may be seen in the example illustrated in FIG. 8c that a further increase of the first and second currents i₁ and i₂ leads to a further increase of the second magnetic flow density B″ and thus to the saturation of the second magnetic core area 112.

The magnetization of the first and second magnetic core areas 110 and 112 in FIG. 8b here corresponds to the time t₁ of FIG. 6c, while the magnetization of the first and second magnetic core areas 110 and 112 in FIG. 8c corresponds to the time t₂ of FIG. 6c.

In other words, with an increasing magnetization of the toroidal core 134 by the magnetization current in the divided primary coils 102 and 104, one of the two points in the toroidal core (in the area of the coil N1 or in the area of the coil N2) reaches the point of maximum magnetization earlier than the other one (t₁) (see FIG. 8b). At this moment of maximum magnetization of the toroidal core 134, the coil changes its magnetic characteristics, so that the electric resistivity of the coil also changes and takes on a minimum value.

Thus, also the voltage across the respective coil decreases strongly and thus changes the voltage divider across the coil and the resistor in the respective current path (R1+N1 or R2+N2).

With a further increasing magnetization current in the divided primary coil, after a short time also the respective other point of the toroidal core reaches maximum magnetization (maximum of the hysteresis loop) (see FIG. 8c), so that the electric characteristics of the coils N1 and N2 balance and lead to a compensation of the voltage divider differences in the two current paths (t₂).

The differential amplifier 128 taps the voltage differences across the two coils N1 and N2 (see FIG. 9). For the short period of time between t₁(t_{B′max}) and t₂(t_{B″max}), due to the different electric characteristics of N1 and N2 a voltage difference is measured at the input. The output of the differential amplifier 128 is supplied to a peak detector 132 which enables a high temporal resolution for the occurring pulse-like signals.

The use of a triangular voltage as an excitation signal enables a very good linear control for the magnetization of the toroidal core.

Embodiments of the present invention relate to a device and method for the construction of a fluxgate sensor based on a toroidal core construction.

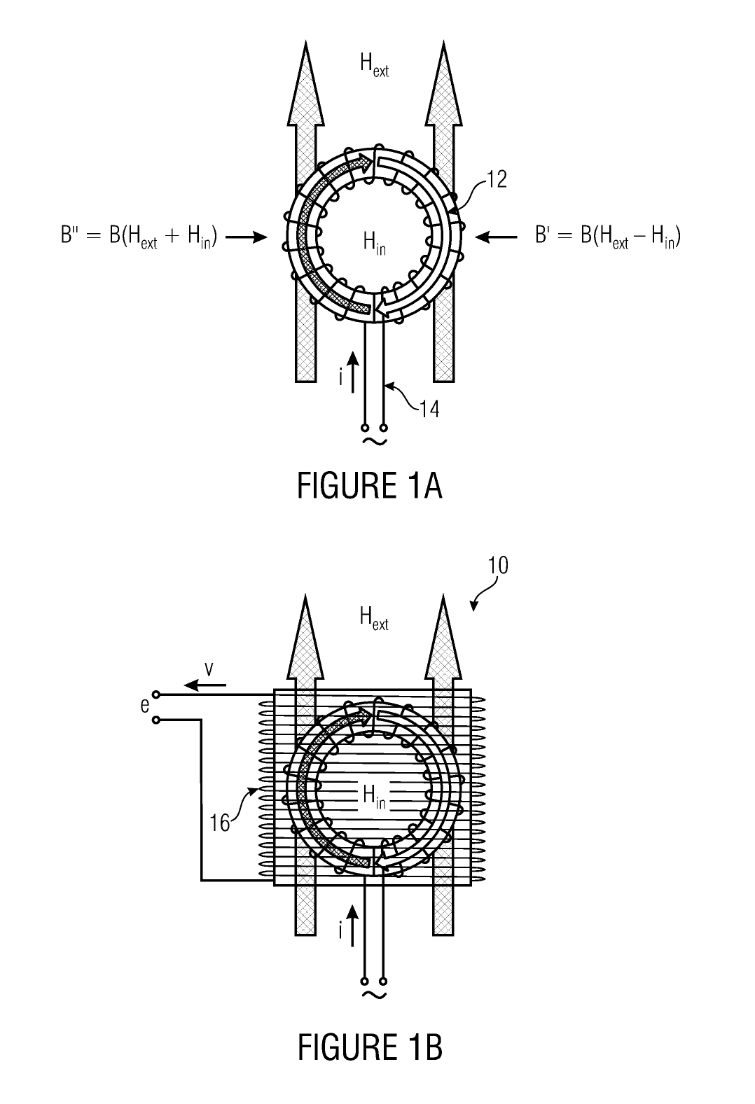

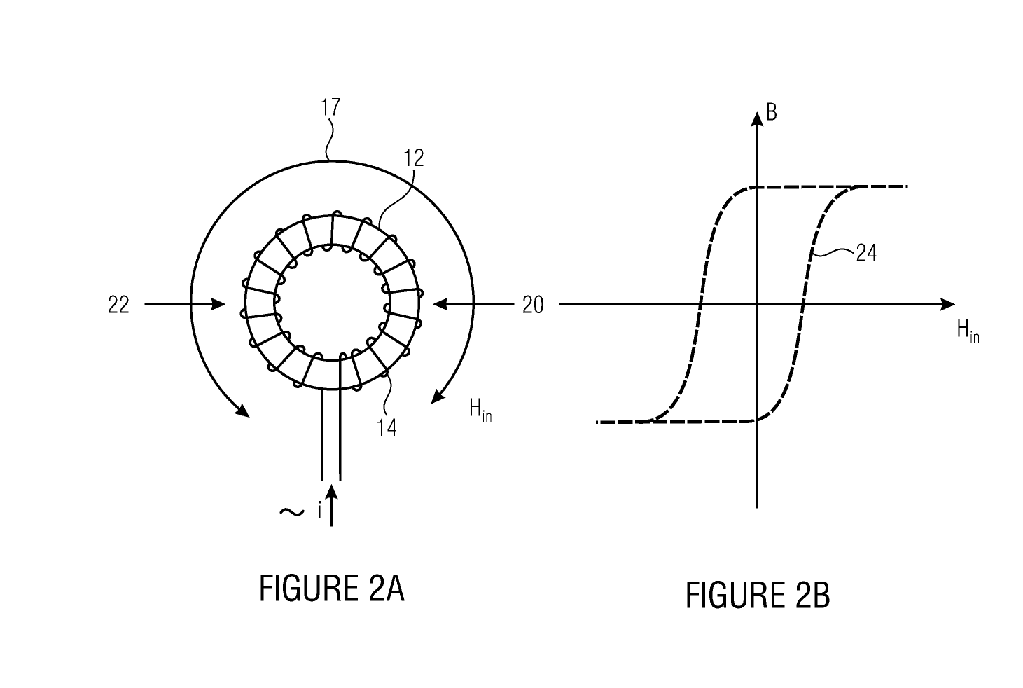

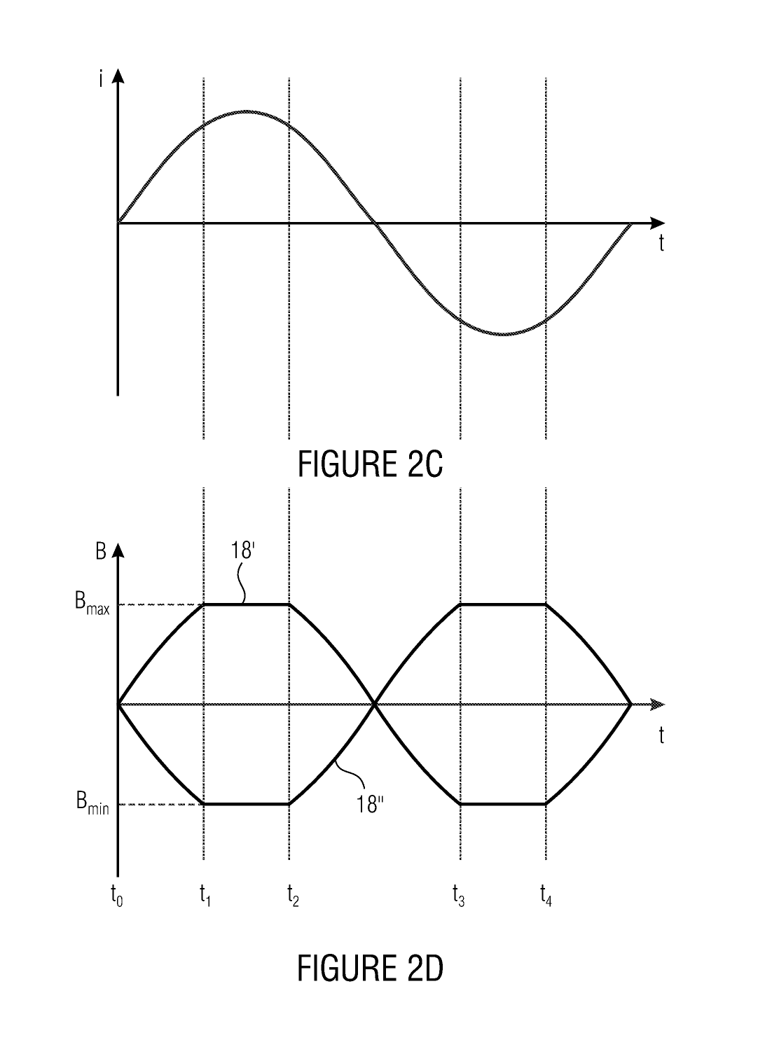

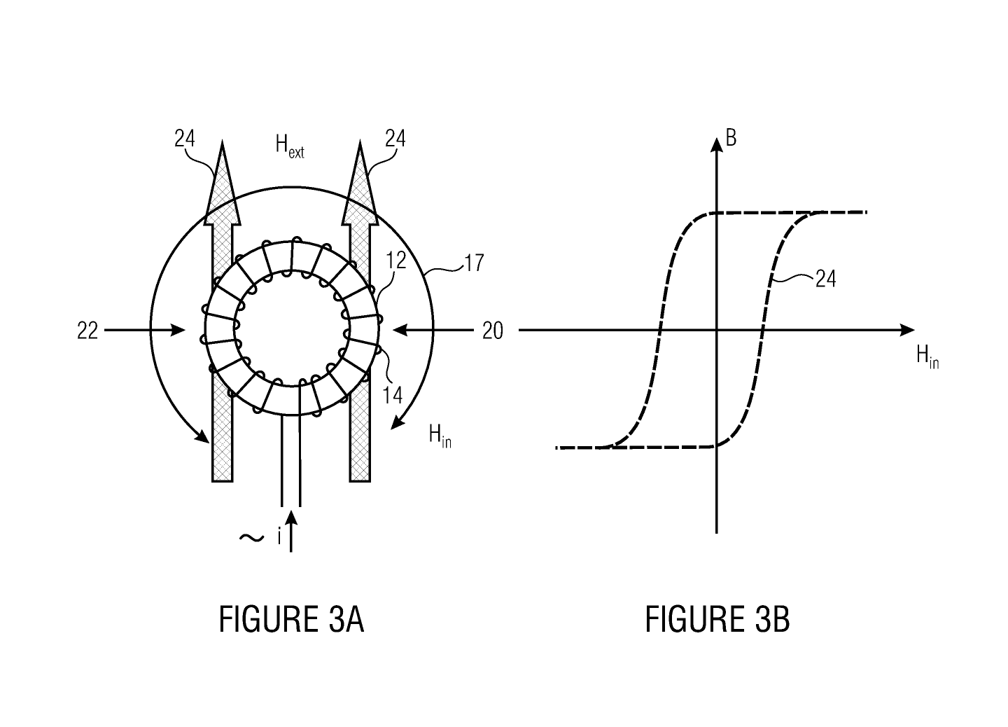

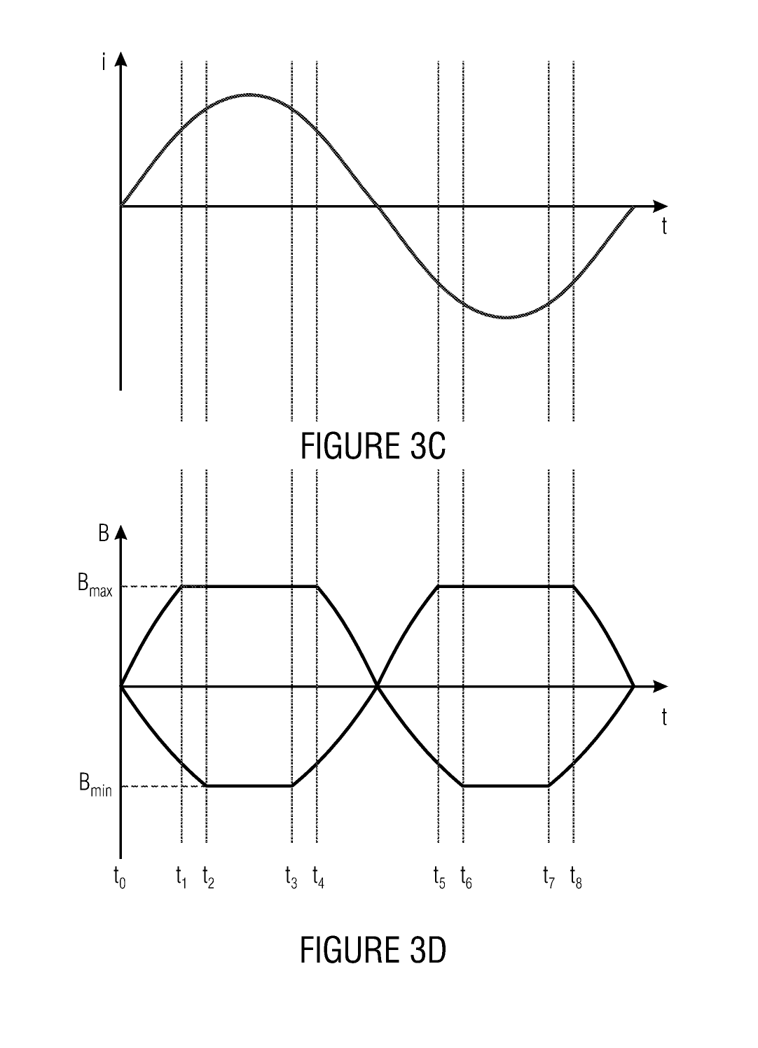

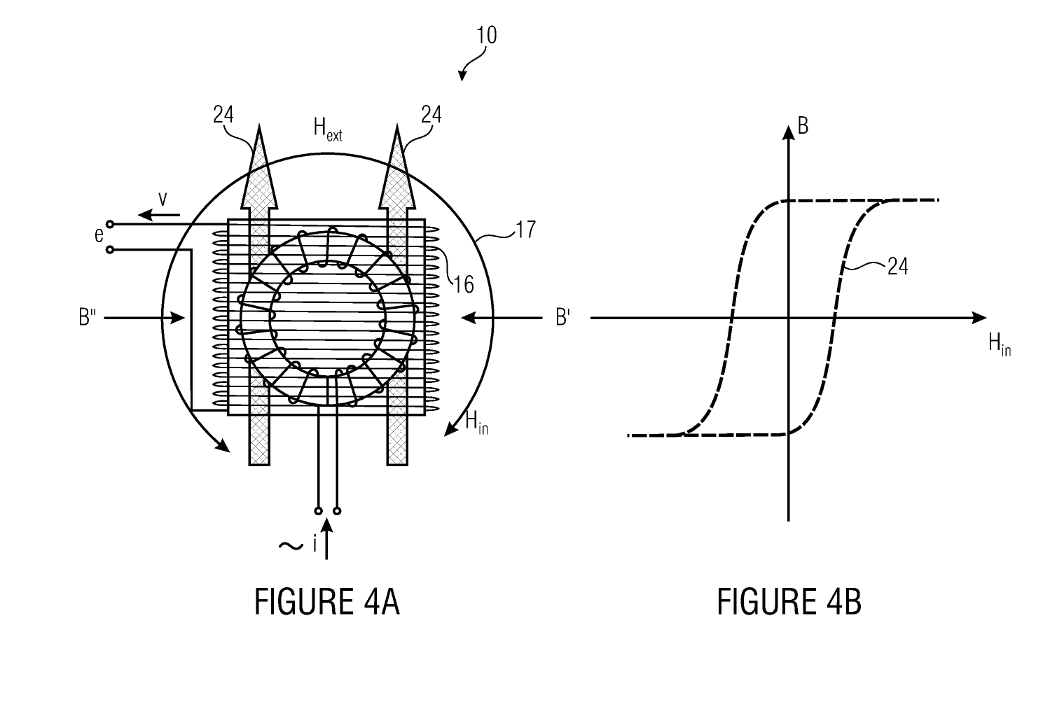

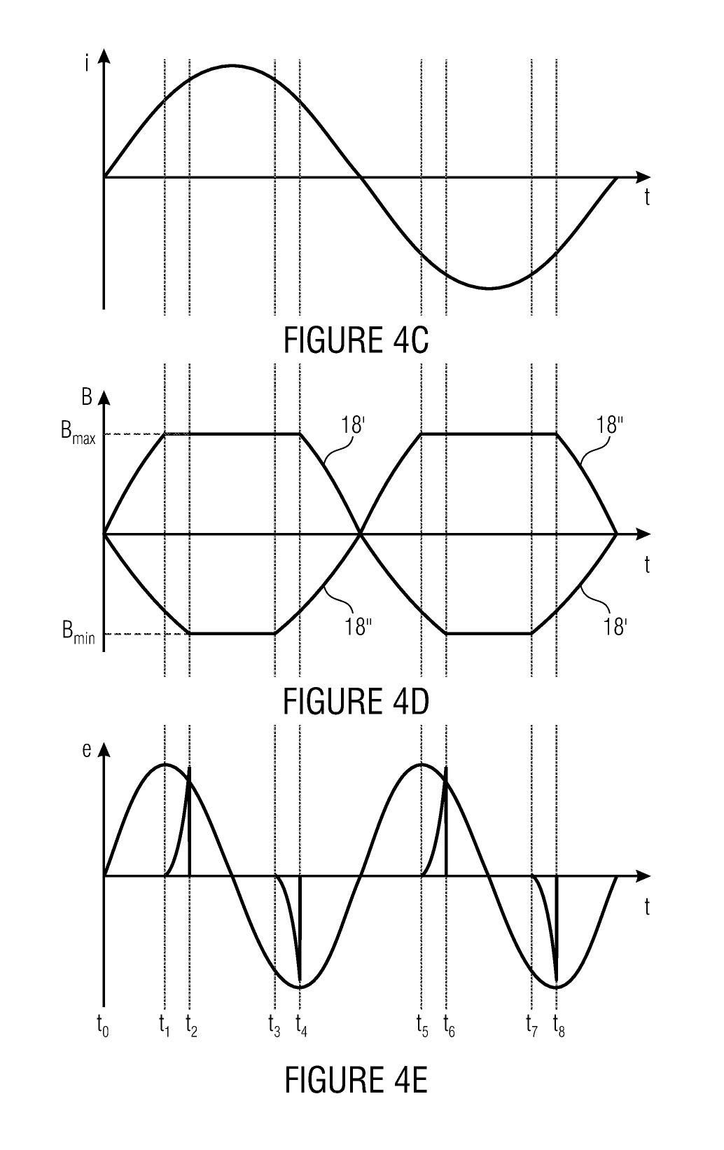

Further embodiments relate to the use of a single coil winding (with classic fluxgate sensors, a primary coil around the toroidal core and a secondary coil around the primary coil is used, see FIG. 1a).

In embodiments, the primary coil may be used as an excitation coil and at the same time as a detection coil (with classic fluxgate sensors, the primary coil is only used for excitation, the secondary coil only for the detection of the magnetically induced coil).

Further embodiments relate to the measurement of the magnetic field strength based on current changes in the divided primary coil as an effect overlaying of the external magnetic field and the excitation magnetization in the toroidal core (with classic fluxgate sensors, the magnetic field strength is measured as the effect of the voltage magnetically induced in the secondary coil).

In embodiments, a flexible frequency selection for the excitation current and the measurement without calibration is possible (classic fluxgate sensors have to be operated with a fixed frequency due to the matching of primary and secondary coils).

Embodiments enable an extension of the measurement range with respect to the frequency of the external magnetic field, in particular with sensitive sensors (classic fluxgate sensors with high sensitivity necessitate a high winding number for the secondary coil and thus show a limitation with respect to the maximum measurable frequency with respect to the external magnetic field).

In embodiments, even with small dimensions the fluxgate sensor comprises high sensitivity (classic fluxgate sensors necessitate a high winding number for the secondary coil for high sensitivity and thus have larger dimensions).

Embodiments comprise a high temporal resolution for changing external magnetic fields by precise sampling times in the detector signal (classic fluxgate sensors provide a sinusoidal signal with a fixed frequency as the output signal of the secondary coil, wherein the sinusoidal signal is amplitude-modulated by the external magnetic field and only allows a certain temporal resolution.

Embodiments of the present invention provide a simple, precise and cost-effective method for the measurement of very weak magnetic field strengths (in the range of pT).

The inventive magnetic field sensor is specially suitable for the measurement of biomagnetic signals (e.g. magnetic cardiogram (MCG)). Further, the inventive magnetic field sensor 100 enables clearly simpler measurements of biomagnetic signals as compared to classic methods, like, e.g., SQUIT.

Embodiments of the present invention relate to a sensor for measuring magnetic fields. In the center of the application scenario there is the use of a sufficiently sensitive sensor for the measurement of very weak magnetic signals. The following aims of measurement value detection, for example, are proposed for the magnetic field sensor. First, measurement of biomagnetic signals with smallest field strengths, e.g. the magnetic signal generated by the heart muscle, the so-called “magnetic cardiogram (MCG)”. Second, balance time measurements for proving the efficiency of shielding. Third, calibration of electromagnets in Helmholtz coils for interference field compensation. Fourth, precise measurement of natural magnetic fields and representation of the vector components, e.g. terrestrial magnetic field. Fifth, measurement of weak geomagnetic fields in stone. Sixth, industrial application based on inductive measurement methods or magnetic field measurement, e.g. testing of material thicknesses or mass determination.

Further embodiments provide a method for detecting an external magnetic field. In a first step, an excitation current is provided which divides onto a first current path with a first coil area and a second current path with a second coil area, wherein the first coil area comprises windings in a first winding direction around a first magnetic core area, wherein the second coil area comprises windings in a second winding direction around a second magnetic core area, and wherein the first coil area and the second coil area pass in parallel to each other. In a second step, a voltage between the first and second coil areas is tapped. In a third step, the external magnetic field is detected based on the voltage difference between the first and second coil areas.

Further embodiments provide a method for detecting an external magnetic field. In a first step, a first current is impressed into a first coil area and a second current is impressed into a second coil area, wherein the first coil area comprises windings in a first winding direction around a first magnetic core area, and wherein the second coil area comprises windings in a second winding direction around a second magnetic core area. In a second step, a voltage is tapped between the first and second coil areas. In a third step, the external magnetic field is detected based on the voltage between the first and second coil areas.

Although some aspects were described in connection with a device, it is obvious that those aspects also represent a description of the corresponding method, so that a block or a member of a device may also be regarded as a corresponding method step or as a feature of a method step. Analogously to that, aspects which were described in connection with or as a method step may also represent a description of a corresponding block or detail or feature of a corresponding device. Some or all of the method steps may be implemented by a hardware apparatus (or using a hardware apparatus), like, for example, a microprocessor, a programmable computer or an electronic circuit. In some embodiments, some or several of the most important method steps may be executed by such an apparatus.

The above-described embodiments merely represent an illustration of the principles of the present invention. It is obvious that modifications and variations of the arrangements and details described herein are clear to other persons skilled in the art. It is thus intended for the invention to be only limited by the scope of the following patent claims and not by the specific details presented herein by the description and explanation of the embodiments.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A magnetic field sensor, comprising:
a first current path comprising a first coil area and a second current path comprising a second coil area, wherein the first coil area comprises windings in a first winding direction around a first magnetic core area, and wherein the second coil area comprises windings in a second winding direction around a second magnetic core area, and wherein the first coil area and the second coil area pass in parallel to each other;
a signal generator which is implemented to provide an excitation current which divides into the first and second current paths; and
an evaluator which is implemented to tap a voltage between the first and second coil areas to detect an external magnetic field based on the voltage.

2. The magnetic field sensor according to claim 1, wherein the first winding direction and the second winding direction are different.

3. The magnetic field sensor according to claim 1, wherein a number of windings of the first coil area is equal to a number of windings of the second coil area.

4. The magnetic field sensor according to claim 1, wherein the magnetic field sensor comprises a magnetic core which comprises the first and second core areas.

5. The magnetic field sensor according to claim 1, wherein the magnetic field sensor comprises a first and second magnetic core, wherein the first magnetic core comprises the first core area, and wherein the second magnetic core comprises the second core area.

6. The magnetic field sensor according to claim 1, wherein the magnetic field sensor comprises a first and second coil, wherein the first coil comprises the first coil area, and wherein the second coil comprises the second coil area.

7. The magnetic field sensor according to claim 1, wherein the magnetic field sensor comprises a bridge circuit, wherein the first current path forms a first bridge branch of the bridge circuit, and wherein the second current path forms a second bridge branch of the bridge circuit, and wherein the evaluator is implemented to tap the voltage between the first and second bridge branches.

8. The magnetic field sensor according to claim 7, wherein the magnetic field sensor comprises a first and a second resistor, wherein the first bridge branch comprises the first resistor and the second bridge branch comprises the second resistor.

9. The magnetic field sensor according to claim 7, wherein the first and second bridge branches are each connected in series between a reference terminal and the signal generator, wherein the reference terminal is implemented to provide a reference potential.

10. The magnetic field sensor according to claim 1, wherein the signal generator is implemented to generate a triangular voltage, a square-wave voltage or a sinusoidal voltage, wherein the excitation current depends on the voltage.

11. The magnetic field sensor according to claim 1, wherein the evaluator comprises a differential amplifier which is implemented to tap and amplify the voltage between the first and second coil areas in order to acquire an output voltage.

12. The magnetic field sensor according to claim 10, wherein the evaluator comprises a peak value detector or a low-pass filter which is implemented to detect a peak value of the output voltage to detect the external magnetic field.

13. A method for detecting an external magnetic field, comprising:
providing an excitation current which divides into a first current path with a first coil area and a second current path with a second coil area, wherein the first coil area comprises windings in a first winding direction around a first magnetic core area, wherein the second coil area comprises windings in a second winding direction around a second magnetic core area, and wherein the first coil area and the second coil area pass in parallel to each other;
tapping a voltage between the first and second coil areas; and
detecting the external magnetic field based on the voltage between the first and second coil areas.

14. A computer program for executing a method for detecting an external magnetic field, comprising:
providing an excitation current which divides into a first current path with a first coil area and a second current path with a second coil area, wherein the first coil area comprises windings in a first winding direction around a first magnetic core area, wherein the second coil area comprises windings in a second winding direction around a second magnetic core area, and wherein the first coil area and the second coil area pass in parallel to each other;
tapping a voltage between the first and second coil areas; and
detecting the external magnetic field based on the voltage between the first and second coil areas, when the computer program is executed on a computer or microprocessor.
